(19) United States
(12) Patent Application Publication
(10) Pub. No.: US 2007/0092993 A1
(43) Pub. Date: Apr. 26, 2007

(54) Semiconductor device packaging for avoiding metal contamination

(75) Inventors: Kiyonori Oyu, Tokyo (JP); Kensuke Okonogi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/583,157

(22) Filed: Oct. 19, 2006

(30) Foreign Application Priority Data
Oct. 26, 2005 (JP) 2005-311338

(51) Int. Cl. H01L 21/00

(52) U.S. Cl. 438/106

(57) ABSTRACT

A semiconductor device manufacture method includes: bonding a main device surface of a semiconductor chip onto a package tape with adhesive material; and subjecting the semiconductor chip and the package tape to baking to cure the adhesive material. The baking of the semiconductor chip and the package tape is accompanied by supplying blow gas to a rear surface of the semiconductor chip.

### BACKGROUND OF THE INVENTION

1. Field of the Invention

The present invention relates to a semiconductor device and a manufacture method of the same, more particularly, to semiconductor device packaging for improving the reliability of the semiconductor device.

2. Description of the Related Art

The thickness of the semiconductor chip integrated within the semiconductor package has been more and more reduced in order to improve the packaging density. The reduction of the semiconductor chip thickness is accompanied by the removal of damages caused by the backgrinding however, the removal of the back-grinding damages enhances the metal contamination onto the main device surface during the packaging process, and undesirably deteriorates the product reliability of the semiconductor device. Therefore, there is a need for specifying the metal contamination source in the packaging process, and taking measures for avoiding the metal contamination from the contamination source.

FIGS. 1 to 4 illustrate a conventional manufacture process of a BGA-packaged semiconductor device. As shown in FIG. 1, the manufacture process involves adhesive bonding of the main device surface of a semiconductor chip 1 onto a TAB (tape automated bonding) tape 2 with elastomer 3. The TAB tape 2 is provided with inner leads 7. In order to improve the adhesion force, this is followed by baking at a temperature of 150 to 180° C. for several ten minutes. As shown in FIG. 2, the rear surface of the semiconductor chip 1 is then connected with a pressure bonding base 9. The inner leads 7 are bonded onto pads 1a on the semiconductor chip 1 through externally applying mechanical pressures to the inner leads 7 through the opening of the TAB tape 2. The semiconductor device is subjected to heat treatment at a temperature from 150 to 180° C. for several ten seconds in order to improve the bonding force, when the inner leads 7 are bonded on the pads 1a. After the heat treatment, as shown in FIG. 3, the semiconductor chip 1 is sealed with resin 10, and then the semiconductor device is subjected to baking at a temperature of 150 to 180° C. for several hours. The resin 10 is cured by this baking. Finally, as shown in FIG. 4, solder balls 11 are attached with the TAB tape 2 through a solder reflow process. The solder reflow is implemented at a temperature of 250 to 270° C. for several ten seconds.

Such a BGA packaging technique is disclosed in a product catalog of Hitachi Cable Ltd., entitled “μBGA package. CAT. No. B-106D”. According to this catalog, the disclosed BGA packaging technique is adapted to reel to reel process until the singulation of the final package on the TAB tape is completed, and thereby achieves highly reliable and stable production.

The conventional semiconductor packaging technique, however, suffers from the metal contamination of the main device surface on which semiconductor elements are integrated. Referring to FIG. 1, the baking after the adhesive bonding of the semiconductor chip 1 and the TAB tape 2 causes scattering of contamination metal, such as copper, from the surface of the TAB tape 2, and the scattered contamination metal is attached with the rear surface of the semiconductor chip 1. Additionally, when the pressure bonding base 9 contain copper and/or nickel, the copper and/or nickel may be attached with the rear surface of the semiconductor chip 1. The attached contamination metal, such as copper and nickel, travels from the rear surface to the main device surface within the semiconductor chip 1 during the baking for the resin curing shown in FIG. 3. When the contamination metal reaches an active region of the device face, this undesirably causes the increase in the pn-junction leak current and the gate dielectric leak current, resulting in the deterioration of the product reliability. It should be noted that the diffusion speed of contamination metal, such as copper, through semiconductor material, such as silicon, is large, and therefore, the above-described baking causes the contamination metal to reach the main device surface of the semiconductor chip 1. The problem of the metal contamination of the main device surface caused by the metal traveling is serious, especially when the thickness of the semiconductor chip is reduced. The reduction in the thickness of the semiconductor chip is one of the causes of reliability deterioration of recent semiconductor devices.

### SUMMARY OF THE INVENTION

Therefore, an object of the present invention is to avoid metal contamination of the main device surface, and to thereby improve the reliability of the semiconductor device.

In an aspect of the present invention, a semiconductor device manufacture method includes:

(a) bonding a main device surface of a semiconductor chip onto a package tape having an opening by using adhesive material; and

(b) subjecting the semiconductor chip and the package tape to baking to cure the adhesive material. The baking of the semiconductor chip and the package tape is accompanied by supplying blow gas to a rear surface of the semiconductor chip. The blow gas prevents contamination metal scattered from the TAB tape from being attached onto the rear surface of the semiconductor chip, and effectively improves the reliability of the semiconductor device.

Preferably, the temperature of the blow gas is almost the same as the baking temperature at which the baking is implemented; the difference between the blow gas temperature and the baking temperature is preferably within ±10° C.

Preferably, the blow gas is supplied so that a gas flow is generated from the center portion of the semiconductor chip to the peripheral portion. The gas flow is preferably controlled so that no back flow is generated from the package tape to the rear surface of the semiconductor chip.

It is preferable that the blow gas is not circulated after being flown along the semiconductor chip and the package tape; it is preferable that the blow gas is constantly taken from an outside source. This effectively suppresses scattering metal from the package tape to the rear surface of the semiconductor chip during baking of the semiconductor chip and the package tape.

The flow rate of the blow gas preferably ranges from 50 to 100 cm/s.

In a preferred embodiment, the semiconductor device manufacture method additionally includes: (c) attaching a pressure bonding base onto the rear surface of the semiconductor chip, (d) bonding conductive leads prepared on the package tape with pads prepared on the semiconductor chip, (e) detaching the pressure bonding base after the conductive leads are bonded with the pads of the semiconductor chip, (f) sealing the semiconductor chip with resin, (g) curing the resin, and (h) attaching solder balls with the package tape.

In this case, the attaching face between the pressure bonding base and the semiconductor chip is preferably coated with a coating film. The coating film is preferably formed of silicon nitride or silicon carbide. The coating of silicon nitride or silicon carbide effectively avoids contamination metal such as cupper or nickel being attached with the rear surface of the semiconductor chip. This effectively avoids the contamination metal being diffused through the semiconductor chip to reach the main device surface of the semiconductor chip.

The concentration of cupper atoms on the rear surface of the semiconductor chip is preferably reduced below 10¹⁰/cm².

As thus described, the semiconductor device manufacture method according to present invention effectively reduces the metal contamination onto the main device surface of the semiconductor chip, on which elements are integrated, and thereby achieves improving reliability of the semiconductor device.

### BRIEF DESCRIPTION OF THE DRAWINGS

FIGS. 1 to 4 illustrate a conventional semiconductor device manufacture method;

FIG. 5 is a flow chart illustrating a semiconductor device manufacture method according to the present invention;

FIG. 6 is a metal contamination depth profile of a semiconductor chip after back grinding;

FIG. 7 illustrates the state of the semiconductor chip at the rear surface after wet etching, which is implemented to remove contamination metal on the rear surface of the semiconductor chip after the back grinding;

FIG. 8 schematically illustrates steps of bonding a semiconductor chip onto a TAB tape, and then baking the semiconductor chip and the TAB tape bonded together in accordance with the present invention;

FIG. 9 schematically illustrates steps of coupling a pressure bonding base with the rear surface of the semiconductor device, and then bonding inner leads of the TAB tape with pads of the semiconductor chip through pressure bonding;

FIG. 10 schematically illustrates steps of detaching the pressure bonding base from the rear surface of the semiconductor device, and baking the semiconductor chip after sealing with resin;

FIG. 11 schematically illustrates a step of bonding solder balls onto the TAB tape;

FIG. 12 is a table illustrating measured metal concentrations on the main device surfaces of semiconductor devices in embodiments of the present invention;

FIG. 13 illustrates flow of the blow gas supplied to the rear surface during the baking of the bonding face between the semiconductor chip and the TAB tape in first and second embodiments of the present invention;

FIG. 14 illustrates flow of the blow gas supplied to the rear surface during the baking of the bonding face between the semiconductor chip and the TAB tape in third and fourth embodiments of the present invention;

FIG. 15 illustrates flow of the blow gas supplied to the rear surface during the baking of the bonding face between the semiconductor chip and the TAB tape in fifth and sixth embodiments of the present invention; and

FIG. 16 schematically illustrates steps of attaching a pressure bonding base having an attaching face coated with a coating film to the rear surface of the semiconductor chip, and bonding inner leads of the TAB tape to pads of the semiconductor chip through pressure bonding.

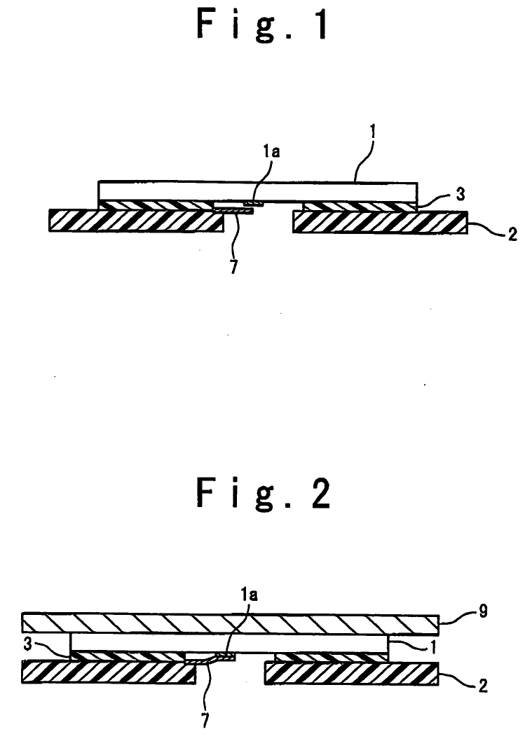

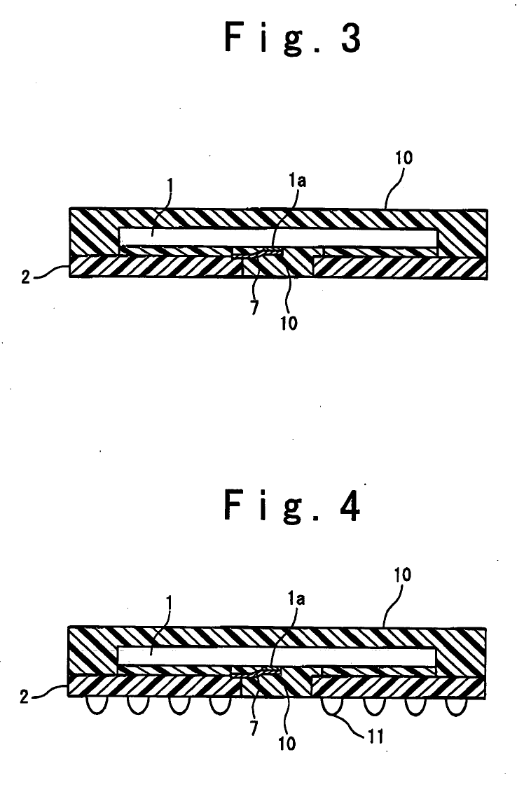

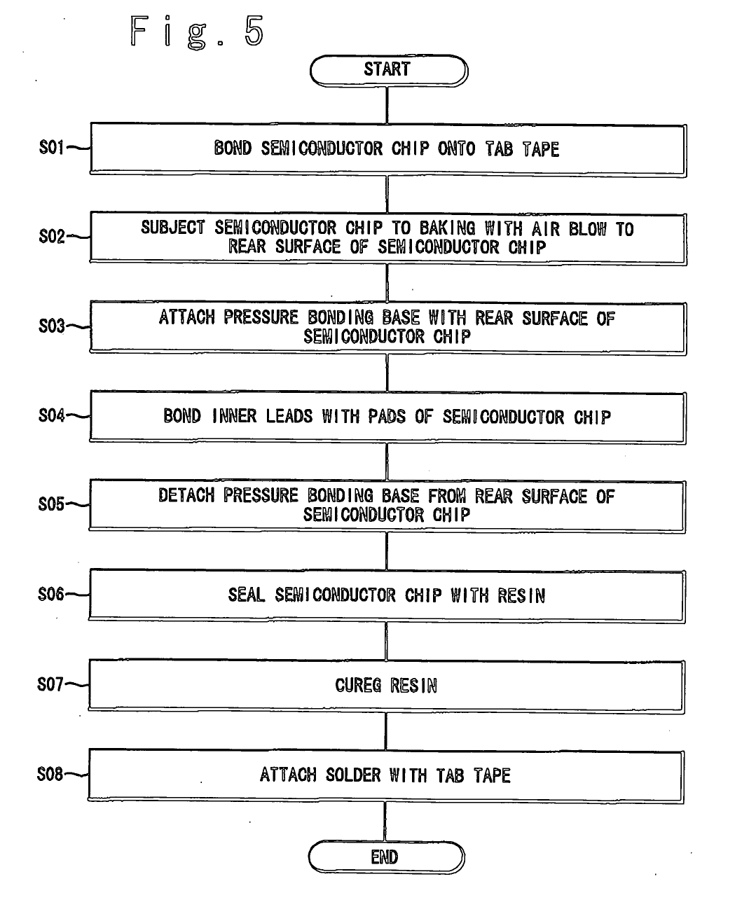

### DESCRIPTION OF THE PREFERRED EMBODIMENTS

### Embodiment 1

FIG. 5 illustrates a manufacture flow of a semiconductor device in a first embodiment according to a semiconductor device manufacture method of the present invention. In this embodiment, the semiconductor device manufacture method is directed to packaging a semiconductor chip into a μBGA package.

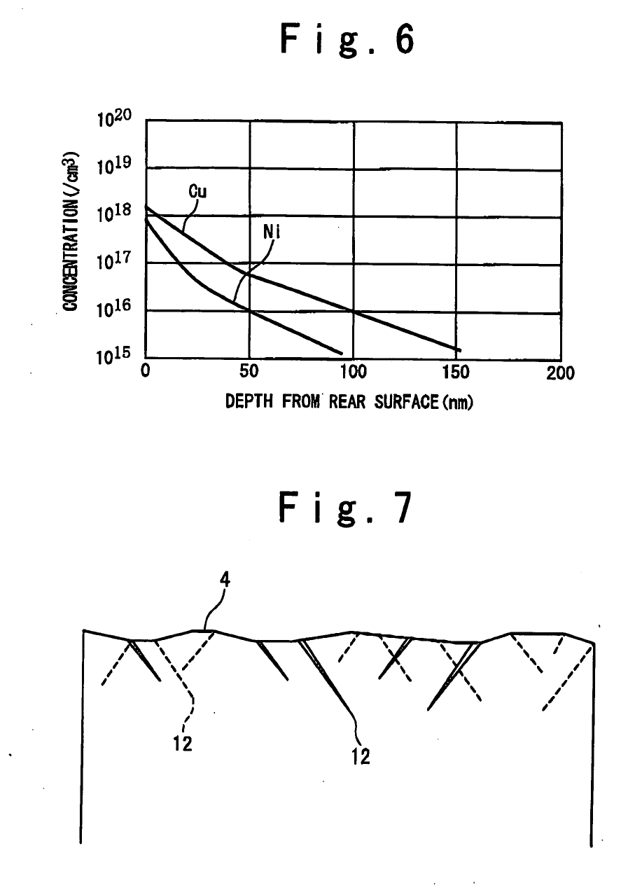

The semiconductor manufacture method in this embodiment begins with back grinding of a wafer within which DRAMs are integrated. The wafer is back-grinded so that the thickness of the wafer is reduced down to 100 μm. Specifically, the back grinding involves rough grinding with a grinding stone of #400 abrasive powders to reduce the wafer thickness down to 120 μm, and fine grinding with a grinding stone of #2000 abrasive powders to reduce the wafer thickness down to 100 μm. As shown in FIG. 6, the rear surface of the wafer is contaminated with metal, such as cupper and nickel, to the depth of 0.1 μm from the rear surface after the back grinding.

In order to remove the contamination metal, the back-grinded rear surface, denoted by the numeral 4 in FIG. 7, is wet-etched with an etched depth of 1 μm by using an enchant of HF and HNO₃ mixture. This wet-etching achieves the removal of back-grinding damages 12 as shown in FIG. 7. In an alternative embodiment, other techniques free from metal contamination, such as chemical mechanical polishing (CMP) and plasma etching, may be used in place of the wet etching.

The removal of the back-grinding damages 12 through wet-etching effectively improves the anti-cracking property of the wafer. Obtaining semiconductor chips with a thin thickness requires reducing the wafer thickness; however, a thin wafer with grinding damages is easy to be broken. Therefore, obtaining a thin wafer requires removing back-grinding damages on the rear surface through wet-etching or other techniques.

The removal of the back-grinding damages 12 on the rear surface, however, causes reduction of the metal trapping capacity of the rear surface. The back-grinding damages 12 function as metal traps on the rear surface, when metal contamination occurs during the packaging process, and therefore effectively suppresses diffusing contamination metal from the rear surface to the main device surface of the wafer; it should be noted that the main device surface designates a surface on which elements, such as DRAMs, are integrated. As thus described, thinning the wafer is undesirably accompanied by the reduction in the metal trapping capacity of the rear surface, causing the main device surface of the wafer to be easily subjected to metal contamination during the packaging process.

Such problem is effectively solved by the semiconductor device manufacture method of this embodiment as follows.

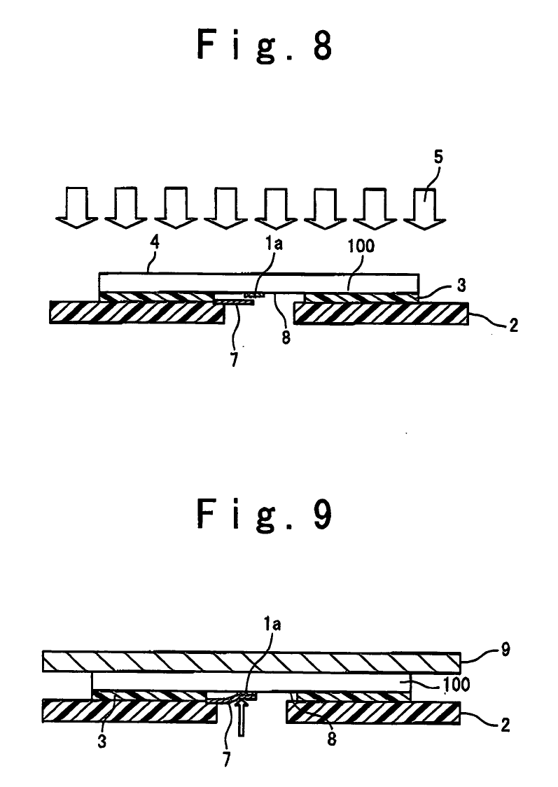

As shown in FIG. 8, the semiconductor device manufacture method in this embodiment involves dicing of a back-grinded wafer, and then bonding a main device surface 8 of a semiconductor chip 100 onto a TAB tape 2 with elastomer 3 (Step S01 in FIG. 5). The elastomer 3 is used as adhesive material to secure the semiconductor chip 100 on the TAB tape 2. The TAB tape 2 is provided with inner leads 7.

This is followed by baking at 175° C. for 20 minutes to cure the elastomer 3 disposed between the semiconductor chip 100 and the TAB tape 2 (Step S02 in FIG. 5). In this embodiment, the baking is accompanied by supplying hot air 5 of 175° C. to the rear surface 4 of the semiconductor chip 100. The flow rate of the hot air preferably ranges from 50 to 100 cm/s. The hot air 5 functions as blow gas, and effectively shields the rear surface 4 of the semiconductor chip 100 from contamination metal, such as cupper, scattered from the TAB tape 2. In this embodiment, the hot air 5 is blown by a hot air nozzle covering the whole of the rear surface 4 of the semiconductor chip 100.

As shown in FIG. 9, a pressure bonding base 9 is then attached with the rear surface 4 of the semiconductor chip 100 (Step S03 in FIG. 5). This is followed by pressure bonding of the inner leads 7 with pads 1a on the main device surface 8 of the semiconductor chip 100 through externally applying pressures through the opening of the TAB tape 2 (Step S04 in FIG. 5). Specifically, the surface temperature of the pressure bonding base 9 is controlled to 175° C., and the inner leads 7 are pressed onto the pads 1a with pressing heads (not shown). After the pressure bonding, the pressure bonding base 9 is detached from the rear surface 4 of the semiconductor chip 100 (Step S05 in FIG. 5).

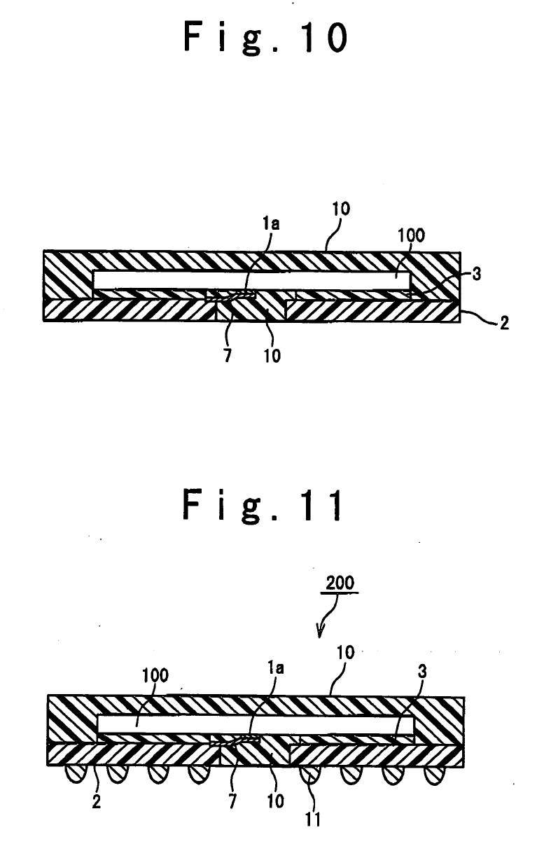

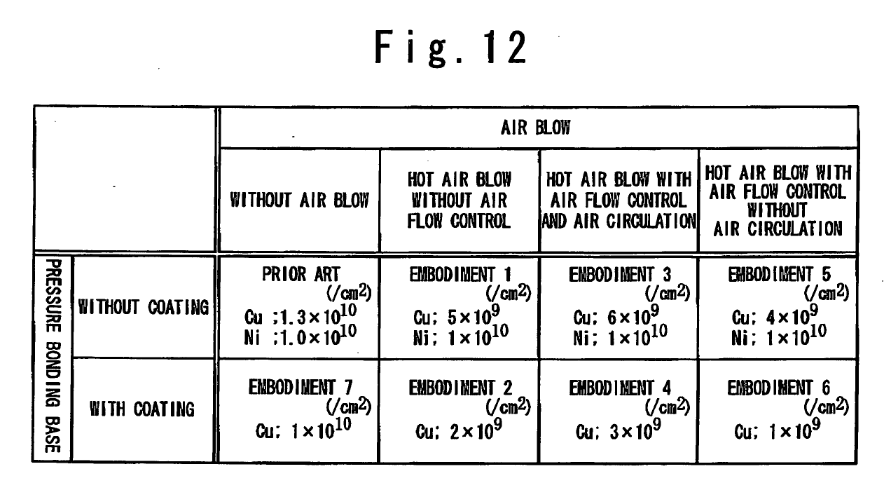

As shown in FIG. 10, this is followed by sealing the semiconductor chip 100 with thermosetting resin 10 (Step S06 in FIG. 5), and curing the resin 10 through 6-hour baking at 175° C. (Step S07 in FIG. 5). Finally, solder balls 11 are attached onto the TAB tape 2 through solder reflow at 265° C. for 15 seconds (Step S08 in FIG. 5). This completes a μBGA-packaged semiconductor device 200.

The air blow of the hot air 5 shown in FIG. 8 effectively shields the rear surface 4 of the semiconductor chip 100 from the metal scattered from the TAB tape 2, and thereby reduces metal contamination of the main device surface 8 of the semiconductor chip 100. FIG. 12 is a table illustrating metal concentrations on rear surfaces of the semiconductor chip 100 in this embodiment and the semiconductor chip 1 in the prior art. In this embodiment, the concentration of cupper atoms on the rear surface 4 of the semiconductor chip 100 is reduced below 10¹⁰/cm². Specifically, the concentration of cupper atoms on the rear surface 4 is reduced down to 5×10⁹/cm² in the average over the chip. On the other hand, the concentration of cupper atoms on the rear surface of the semiconductor chip is as high as 1.3×10⁹/cm² in the prior art in the average over the chip. This proves that the air blow of the hot air 5 shown in FIG. 8 effectively shields the rear surface 4 of the semiconductor chip 100 from the cupper scattered from the TAB tape 8, and effectively suppresses metal contamination of the rear surface 4 of the semiconductor chip 100. The shielding of the rear surface 4 of the semiconductor chip 100 effectively prevents the contamination metal from reaching the main device surface 8 of the semiconductor chip 100 when the semiconductor chip 100 is subjected to the baking (Step S07 in FIG. 5) after the sealing, and avoids malfunction of the elements integrated on the main device surface 8.

### Embodiment 2

In a second embodiment, as shown in FIG. 16, the pressure bonding base 9, which is attached to the rear surface 4 of the semiconductor chip 100 at Step S03, is covered with a coating film 20 on the attaching surface. The coating film 20 may be formed of a silicon nitride film or a silicon carbide film, while the respective process steps in the second embodiment are basically identical to the corresponding steps in the first embodiment.

The coating film 20 effectively avoids metal contamination on the rear surface 4 of the semiconductor chip 100 even when the pressure bonding base 9 contains cupper and/or nickel. The semiconductor device manufacture method in the second embodiment causes an advantageous effect of suppressing the contamination of the metal contained in the pressure bonding base 9 onto the rear surface 4 of the semiconductor chip 100, in addition to the advantageous effect of the semiconductor device manufacture method in the first embodiment. This effectively prevents the contamination metal from reaching the main device surface 8 of the semiconductor chip 100 when the semiconductor chip 100 is subjected to the baking (Step S07 in FIG. 5) after the sealing, and avoids malfunction of the elements integrated on the main device surface 8.

The metal concentration on the rear surface 4 of the semiconductor chip 100 in the second embodiment is depicted in FIG. 12. In the second embodiment, the concentration of cupper atoms on the rear surface 4 of the semiconductor chip 100 is about 2×10⁹/cm² in the average over the chip. This proves that the hot air 5 effectively shields the rear surface 4 of the semiconductor chip 100 from cupper scattered from the TAB tape 2, and the coating film 20 effectively avoids the metal contained in the pressure bonding base 9 being attached onto the rear surface 4 of the semiconductor chip 100.

As thus described, the semiconductor device manufacture method in the second embodiment further reduces the metal contamination on the main device surface of the semiconductor chip 100 compared to that in the first embodiment, and thereby effectively achieves manufacture of a highly reliable semiconductor device.

### Embodiment 3

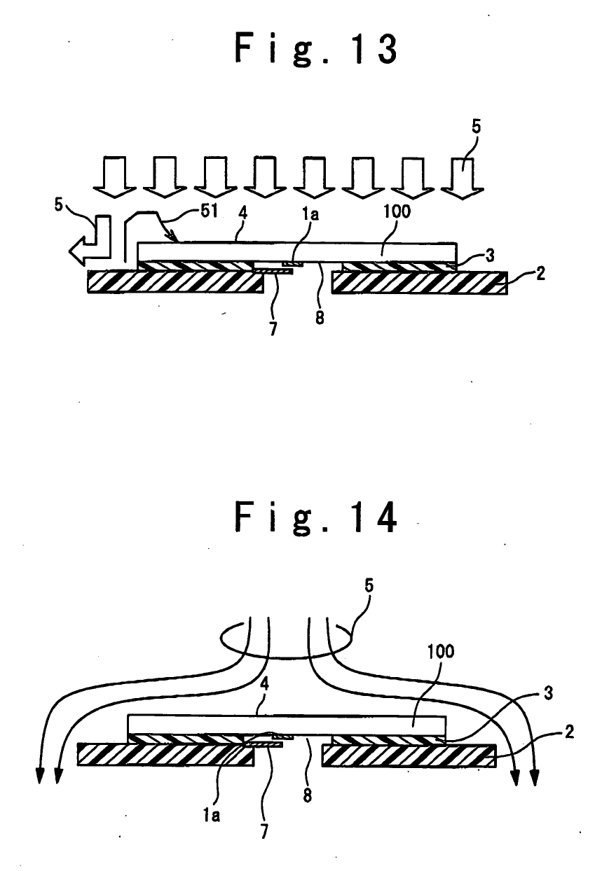

Referring to FIG. 13, one issue of the semiconductor device manufacture method in the first embodiment is that the hot air 5 may be partially flown back from the TAB tape 2 to the rear surface 4. It should be noted that the back flow to the rear surface 4 is denoted by the numeral 51 in FIG. 13. The back flow 51 may cause metal contamination from the TAB tape 2.

In a third embodiment, as shown in FIG. 14, the flow of the hot air 5 from the hot air nozzle is controlled and thereby directed from the center portion of the rear surface 4 of the semiconductor chip 100 to the peripheral portion thereof. The hot air 5 is selectively blown at the center portion of the rear surface 4, and is evacuated from exhaust outlets (not shown) positioned near the edge of the semiconductor chip 100. The respective process steps in the third embodiment are basically identical to the corresponding steps in the first embodiment.

In the third embodiment embodiment, the hot air 5 evacuated from the exhaust outlets is circulated to the hot air nozzle, and then supplied to the rear surface 4 of the semiconductor chip 100 again. Although the circulation of the hot air 5 may seem to cause the metal scattered from the TAB tape 2 to be attached onto the rear surface 4 of the semiconductor chip 100, the metal contamination caused by the circulation of the hot air 5 is not so serious. The concentration of the metal attached onto the rear surface 4 is sufficiently reduced during the circulation, because most of the metal scattered from the TAB tape 2 is trapped on the inner wall of the circulation duct.

In the third embodiment, as shown in FIG. 14, the flow of the hot air 5 is directed from the center portion of the rear surface 4 of the semiconductor chip 100 to the peripheral portion thereof during the baking at Step S02 in FIG. 5, and thereby the back flow 51 from the TAB tape 2 to the rear surface 4 of the semiconductor chip 100, which may contain contamination metal, is effectively suppressed. Additionally, the most of the metal scattered from the TAB tape 2 is trapped on the inner wall of the circulation duct. Therefore, the concentration of the contamination metal on the rear surface 4 is sufficiently reduced. This effectively prevents the contamination metal from reaching the main device surface 8 of the semiconductor chip 100 when the semiconductor chip 100 is subjected to the baking (Step S07 in FIG. 5) after the sealing, and avoids malfunction of the elements integrated on the main device surface 8.

The metal concentration on the rear surface 4 of the semiconductor chip 100 in the third embodiment is depicted in FIG. 12. In the third embodiment, the concentration of cupper atoms on the rear surface 4 of the semiconductor chip 100 is about 6×10⁹/cm² in the average over the chip, and the concentration of nickel atoms is about 1×10¹⁰/cm². This proves that the hot air 5 effectively shields the rear surface 4 of the semiconductor chip 100 from cupper scattered from the TAB tape 2 in the third embodiment.

As thus described, the semiconductor device manufacture method in the third embodiment further reduces the metal contamination on the main device surface of the semiconductor chip 100 compared to the first embodiment, and thereby effectively achieves manufacture of a highly reliable semiconductor device.

### Embodiment 4

Respective process steps in a fourth embodiment are basically identical to the corresponding steps in the third embodiment. The difference of the fourth embodiment from the third embodiment is that the pressure bonding base 9, which is attached to the rear surface 4 of the semiconductor chip 100 at Step S03, is covered with a coating film 20 on the attaching surface in the fourth embodiment, as shown in FIG. 16. The coating film 20 may be formed of a silicon nitride film or a silicon carbide film.

The coating film 20 effectively avoids metal contamination on the rear surface 4 of the semiconductor chip 100 even when the pressure bonding base 9 contains cupper and/or nickel. The semiconductor device manufacture method Win the fourth embodiment causes an advantageous effect of suppressing the contamination of the metal contained in the pressure bonding base 9 onto the rear surface 4 of the semiconductor chip 100, in addition to the advantageous effect of the semiconductor device manufacture method in the third embodiment. This effectively prevents the contamination metal from reaching the main device surface 8 of the semiconductor chip 100 when the semiconductor chip 100 is subjected to the baking (Step S07 in FIG. 5) after the sealing, and avoids malfunction of the elements integrated on the main device surface B.

The metal concentration on the rear surface 4 of the semiconductor chip 100 in the fourth embodiment is depicted in FIG. 12. In the fourth embodiment, the concentration of cupper atoms on the rear surface 4 of the semiconductor chip 100 is about 3×10⁹/cm² in the average over the chip. This proves that the hot air 5 effectively shields the rear surface 4 of the semiconductor chip 100 from cupper scattered from the TAB tape 2, and the coating film 20 effectively avoids the metal contained in the pressure bonding base 9 being attached onto the rear surface 4 of the semiconductor chip 100.

As thus described, the semiconductor device manufacture method in the fourth embodiment further reduces the metal contamination on the main device surface of the semiconductor chip 100 compared to the third embodiment, and thereby effectively achieves manufacture of a highly reliable semiconductor device.

### Fifth Embodiment

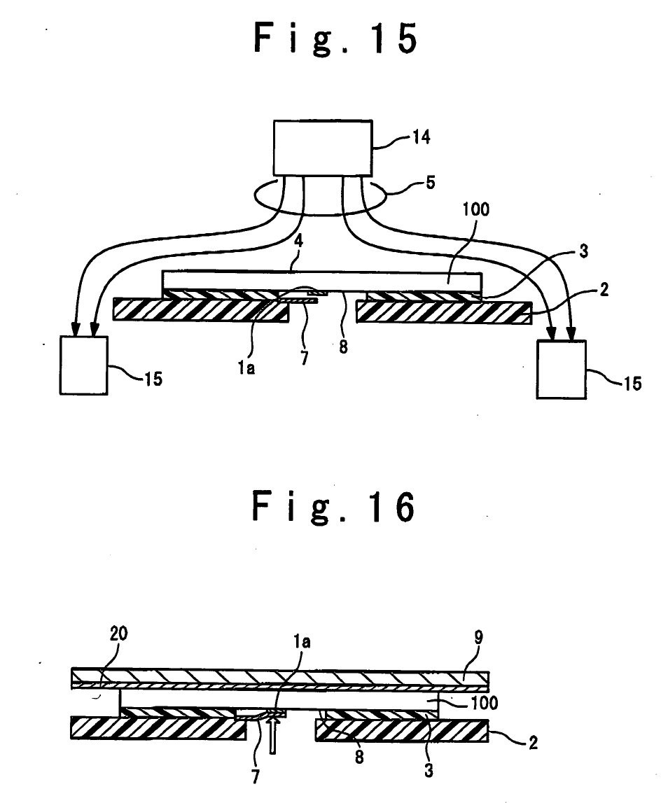

Respective process steps in a fifth embodiment are basically identical to the corresponding steps in the third embodiment. As shown in FIG. 15, the flow of the hot air 5 from the hot air nozzle 14 is controlled and directed from the center portion of the rear surface 4 of the semiconductor chip 100 to the peripheral portion thereof, and the hot air 5 is evacuated from the exhaust outlets 15 positioned near the edge of the semiconductor chip 100.

The difference of the fifth embodiment from the third embodiment is that the hot air 5 is not circulated; fresh air is taken from an outside source to generate fresh hot air 5, and the fresh hot air 5 is supplied to the rear surface 4 of the semiconductor chip 100. The hot air 5 introduced into the exhaust outlets 15, which may contain contamination metal, such as cupper, is exhausted to the external world through a clarification apparatus.

In the fifth embodiment, as shown in FIG. 15, the flow of the hot air 5 is directed from the center portion of the rear surface 4 of the semiconductor chip 100 to the peripheral portion thereof during the baking at Step S02 in FIG. 5, and thereby the back flow 51 from the TAB tape 2 to the rear surface 4 of the semiconductor chip 100, which may contain contamination metal, is effectively suppressed. Additionally, the hot air 5 is generated from fresh air taken from the outside source. Such flow control of the hot air 5 largely reduces the concentration of the contamination metal, such as cupper, attached onto the rear surface 4 of the semiconductor chip 100 from the TAB tape 2. This effectively prevents the contamination metal from reaching the main device surface 8 of the semiconductor chip 100 when the semiconductor chip 100 is subjected to the baking (Step S07 in FIG. 5) after the sealing, and avoids malfunction of the elements integrated on the main device surface 8.

The metal concentration on the rear surface 4 of the semiconductor chip 100 in the fifth embodiment is depicted in FIG. 12. In the fifth embodiment, the concentration of cupper atoms on the rear surface 4 of the semiconductor chip 100 is about 4×10⁹/cm² in the average over the chip, and the concentration of nickel atoms is about 1×10¹⁰/cm². This proves that the hot air 5 effectively shields the rear surface 4 of the semiconductor chip 100 from contamination metal scattered from the TAB tape 2, such as cupper, in the fifth embodiment.

As thus described, the semiconductor device manufacture method in the fifth embodiment further reduces the metal contamination on the main device surface of the semiconductor chip 100 compared to those in the first and third embodiments, and thereby effectively achieves manufacture of a highly reliable semiconductor device.

### Embodiment 6

Respective process steps in a sixth embodiment are basically identical to the corresponding steps in the fifth embodiment. The difference is that the pressure bonding base 9, which is attached to the rear surface 4 of the semiconductor chip 100 at Step S03, is covered with a coating film 20 on the attaching surface in the fourth embodiment, as shown in FIG. 16. The coating film 20 may be formed of a silicon nitride film or a silicon carbide film.

The metal concentration on the rear surface 4 of the semiconductor chip 100 in the sixth embodiment is depicted in FIG. 12. In the sixth embodiment, the concentration of cupper atoms on the rear surface 4 of the semiconductor chip 100 is about 1×10⁹/cm² in the average over the chip. This proves that the hot air 5 effectively shields the rear surface 4 of the semiconductor chip 100 from cupper scattered from the TAB tape 2, and the coating film 20 effectively avoids the metal contained in the pressure bonding base 9 being attached onto the rear surface 4 of the semiconductor chip 100.

As thus described, the semiconductor device manufacture method in the sixth embodiment further reduces the metal contamination on the main device surface of the semiconductor chip 100 compared to that in the first embodiment, and thereby effectively 1S achieves manufacture of a highly reliable semiconductor device.

### Embodiment 7

Differently from the first to sixth embodiments, in a seventh embodiment, the hot air 5 is not supplied to the rear surface 4 of the semiconductor chip 100 while the semiconductor chip 100 and the TAB tape 2 are subjected to the baking to cure the elastomer 3. Alternatively, the pressure bonding base 9, which is attached to the rear surface 4 of the semiconductor chip 100 at Step S03, is covered with a coating film 20 on the attaching surface in the seventh embodiment, as shown in FIG. 16. The coating film 20 may be formed of a silicon nitride film or a silicon carbide film.

The coating film 20 effectively avoids metal contamination on the rear surface 4 of the semiconductor chip 100 even when the pressure bonding base 9 contains cupper and/or nickel. This effectively prevents the contamination metal from reaching the main device surface 8 of the semiconductor chip 100 when the semiconductor chip 100 is subjected to the baking (Step S07 in FIG. 5) after the sealing, and avoids malfunction of the elements integrated on the main device surface 8.

The metal concentration on the rear surface 4 of the semiconductor chip 100 in the seventh embodiment is depicted in FIG. 12. In the seventh embodiment, the concentration of cupper atoms on the rear surface 4 of the semiconductor chip 100 is about 1×10¹⁰/cm² in the average over the chip. This proves that the coating film 20 effectively avoids the metal contained in the pressure bonding base 9 being attached onto the rear surface 4 of the semiconductor chip 100, compared to the prior art.

As thus described, the semiconductor device manufacture method in the seventh embodiment further reduces the metal contamination on the main device surface of the semiconductor chip 100 compared to that in the first embodiment, and thereby effectively achieves manufacture of a highly reliable semiconductor device.

It is apparent that the present invention is not limited to the above-described embodiments, which may be modified and changed without departing from the scope of the invention.

What is claimed is:

1. A semiconductor device manufacture method comprising:
bonding a main device surface of a semiconductor chip onto a package tape with adhesive material; and
subjecting said semiconductor chip and said package tape to baking to cure said adhesive material,
wherein said baking of said semiconductor chip and said package tape is accompanied by supplying blow gas to a rear surface of said semiconductor chip.

2. The semiconductor device manufacture method according to claim 1, wherein said blow gas is supplied so that a gas flow is generated from a center portion of said rear surface of said semiconductor chip to a peripheral portion of said rear surface.

3. The semiconductor device manufacture method according to claim 2, wherein said gas flow is preferably controlled so that no back flow is generated from said package tape to said rear surface of said semiconductor chip.

4. The semiconductor device manufacture method according to claim 1, wherein said blow gas is not circulated after being flown along said semiconductor chip and said package tape.

5. The semiconductor device manufacture method according to claim 1, wherein a flow rate of said blow gas preferably ranges from 50 to 100 cm/s.

6. The semiconductor device manufacture method according to claim 1, further comprising:
attaching a pressure bonding base onto said rear surface of said semiconductor chip;
bonding conductive leads prepared on said package tape with pads prepared on said semiconductor chip,
detaching said pressure bonding base after said conductive leads are bonded with said pads of said semiconductor chip;
sealing said semiconductor chip with resin;
curing said resin; and
attaching solder balls with said package tape.

7. The semiconductor device manufacture method according to claim 6, wherein an attaching face of said pressure bonding base on which face said semiconductor chip is attached is coated with a coating film.

8. The semiconductor device manufacture method according to claim 7, wherein said coating film is preferably formed of silicon nitride or silicon carbide.

9. The semiconductor device manufacture method according to claim 1, wherein a concentration of cupper atoms on said rear surface of said semiconductor chip is reduced below 10¹⁰/cm².
